(19) United States
(12) Patent Application Publication
(10) Pub. No.: US 2014/0022789 A1
(43) Pub. Date: Jan. 23, 2014

(54) LIGHT CORE STRUCTURE AND MANUFACTURING PROCESS THEREOF

(71) Applicant: LI-YU LIN, New Taipei City (TW)

(72) Inventor: LI-YU LIN, New Taipei City (TW)

(21) Appl. No.: 13/551,637

(22) Filed: Jul. 18, 2012

(51) Int. Cl. F21V 29/00; H05K 13/00; F21V 21/00

(52) U.S. Cl. 362/249.02; 362/249.01; 29/592.1

(57) ABSTRACT

The present invention provides a light core structure and a manufacturing process thereof Firstly, an insulation material that is temperature resistant and has high thermal conductivity is provided to serve as a base material and the base material is used to form a thermal conductive body that has a cylindrical shape, a circular tubular shape, a spherical pillar shape, or a conical pillar shape. Printing techniques are then applied to print solderable conductive metal wiring on a surface of the thermal conductive body and heat is applied to cure the wiring to form a curved surface circuit. Afterwards, SMD bonding technique is applied, together with a fixture, to mount SMD LED elements to the curved surface of the thermal conductive body through soldering. The thermal conductive body is then coupled to an adaptor element through threading or other suitable machining or being used in combination with other thermally conductive bar.

### TECHNICAL FIELD OF THE INVENTION

The present invention generally relates to a light core and a manufacturing process thereof, which provide a light core structure and a manufacturing process thereof that are usable in the manufacture of a lighting device and provide an illumination range close to 360 degrees and achieve an effect of energy saving.

### DESCRIPTION OF THE PRIOR ART

Recently, due to the crisis of greenhouse effect, all countries and people pay more attention to the realization of carbon reduction and energy saving in daily living. Among all the related articles, lighting is the one that is mostly emphasized. For example, the traditional tungsten filament based light core is gradually replaced by an LED (Light-Emitting Diode) light core that consumes less electrical power.

Although the LED light has advantages of consuming less power and improved illumination brightness, it is often structured by mounting a single die or a plurality of dies on a conventional printed circuit board. This makes the light emitting from the LED die(s) can only reach a hemispherical range that covers only 180 degrees of the surface of the circuit board on which the LED dies are mounted. As shown in FIG. 1, a conventional LED light core for illumination purposes is often arranged by setting a range of 120 degrees f the light emitting surface as a standard of lighting. The angular range of 120 degrees only takes two-thirds of the available illumination range. In the drawing, an angular range of 30 degrees on both sides of the light bulb have only about 50% of the lighting power (often referred to partially dark zone). On the bottom side of the printed circuit board, completely no light can reach (often referred to as completely dark zone). This makes it not possible to completely replace the wide illumination range of a conventional tungsten filament light bulb that is a spherical range of completely 360 degrees. Consequently, the existing LED light may still be further improved.

The present invention aims to provide a light core structure that provides an illumination range of approximately 360 degrees and a manufacturing process thereof in order to overcome the above discussed problems.

### SUMMARY OF THE INVENTION

An object of the present invention is to provide a light core structure and a manufacturing process thereof, which provide a light core structure that is usable in the manufacture of a lighting device and provides an illumination range close to 360 degrees and achieves an effect of energy saving.

The present invention first uses an insulation material that is temperature resistant and has high thermal conductivity to serve as a base material and uses the base material to form a thermal conductive body. Techniques, such as curved surface printing, transferring, and transfer printing, are applied to print solderable conductive metal wiring on a surface of the thermal conductive body and heat is applied to cure the wiring to form a curved surface circuit. Afterwards, bonding technique and soldering oven facility are used, together with a fixture, to mount at least one light-emitting element to the curved surface of the thermal conductive body through soldering. Finally, the thermal conductive body is coupled to an adaptor element.

The light core structure manufactured according to the present invention is coupled to an adaptor element and comprises a thermal conductive body having a cylindrical shape, a circular tubular shape, a spherical pillar shape, or a conical pillar shape. The thermal conductive body has an end face and a circumferential surface to each of which a plurality of LEDs is mounted. The LEDs are electrically connected to each other.

The present invention can be extended to another light core structure, which comprises at least one cylindrical thermal conductive body that has a circumferential surface to which a plurality of LEDs is mounted. The LEDs are electrically connected to each other. Two conic pillar shaped thermal conductive bodies are respectively mounted to two ends of the cylindrical thermal conductive body. Each of the conical pillar shaped thermal conductive bodies has an end face and a circumferential surface to each of which a plurality of LEDs is mounted. The LEDs are electrically connected to each other.

The present invention mounts a plurality of LEDs to a thermal conductive body having a cylindrical shape, a circular tubular shape, a spherical pillar shape, or a conical pillar shape. With such an arrangement, when the LEDs emit light, the lights emitting from these LEDs may overlap and supplement each other so as to make an illumination range that is close to 360 degrees and thus overcome the drawbacks of the conventional LED lights.

Further, the thermal conductive body according to the present invention can be coupled in multiplicity to form a pillar like object. With such an arrangement, practical applications of the present invention are made versatile. Further, such a combined arrangement helps increasing illumination brightness of LEDs and expanding illumination range and area.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic view showing illumination effected by a conventional light bulb.

FIG. 2 is a flow chart showing a manufacturing process of a light core according to the present invention.

FIG. 3 is a perspective view showing a first embodiment of the present invention in an assembled form.

FIG. 4 is a perspective view showing assembling of the present invention to a light stem.

FIG. 5 is a perspective view showing the present invention assembled to the light stem.

FIG. 6 is a schematic view showing illumination effected by the bulb according to the present invention.

FIG. 7 is a perspective view showing a first configuration of a second embodiment according to the present invention.

FIG. 8 is a perspective view showing a second configuration of the second embodiment according to the present invention.

FIG. 9 is a perspective view showing an embodiment formed by combining multiple embodiments of the present invention.

FIG. 10 is a perspective view showing a first configuration of a third embodiment according to the present invention.

FIG. 11 is a perspective view showing a second configuration of the third embodiment according to the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

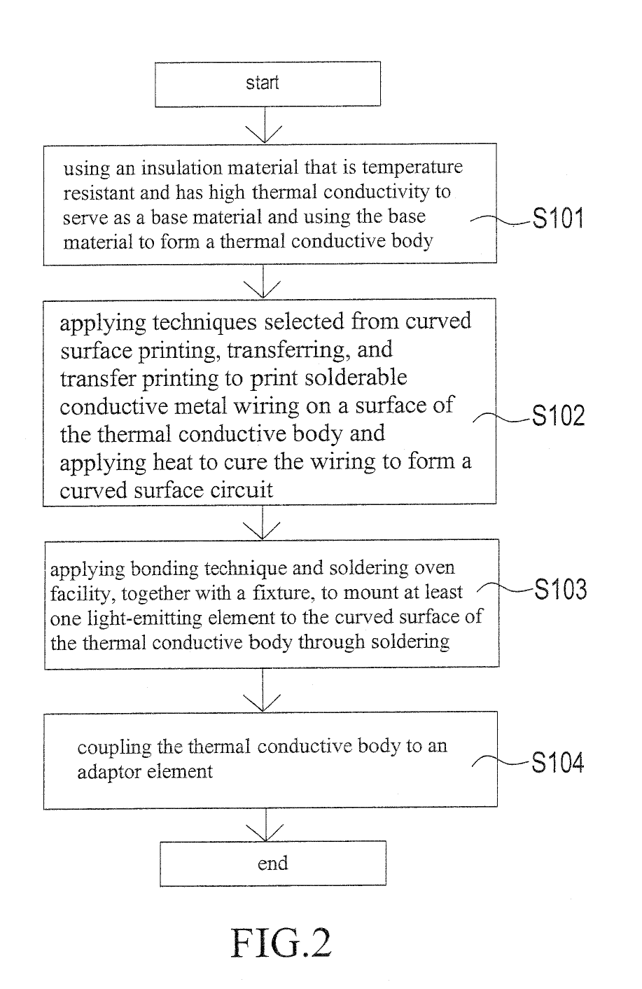

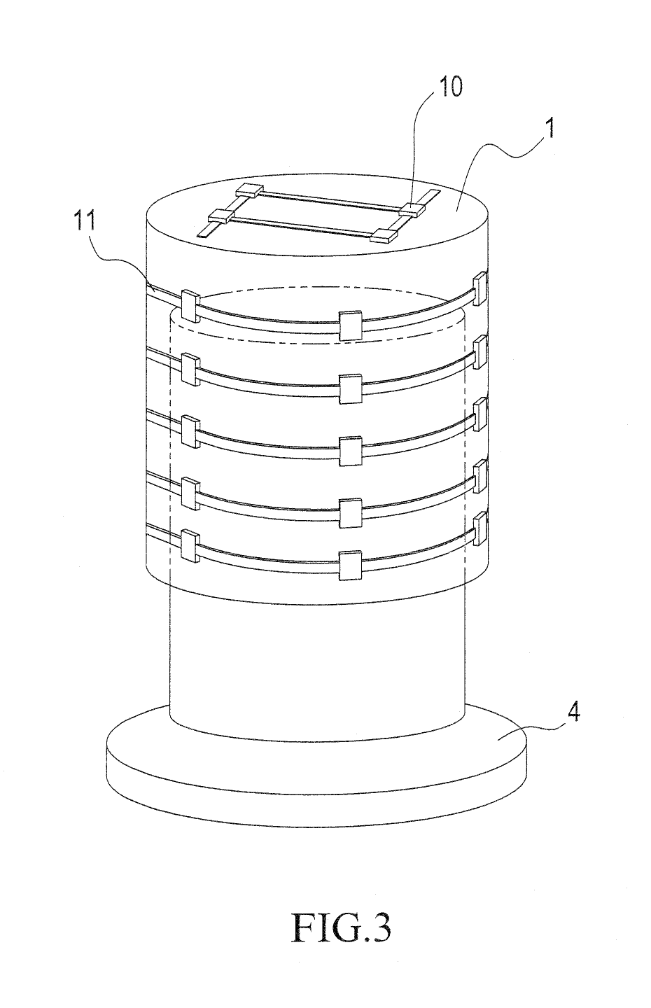

Referring to FIGS. 2 and 3, the present invention provides a manufacturing process that first uses an insulation material that is temperature resistant and has high thermal conductivity to serve as a base material, using the base material to form a cylindrical or a circular tubular thermal conductive body 1 (Step S101). Techniques, such as curved surface printing, transferring, or transfer printing, are then employed to print solderable conductive metal wiring 11 on a surface of the thermal conductive body 1 and heat is applied to cure the wiring to form a curved surface circuit (Step S102). Afterwards, SMD bonding technique is applied, together with the use of a fixture, to mount SMD LED elements to the base material through soldering (Step S103). The main body of the thermal conductive body 1 is coupled to an adaptor element 4 through threading or other suitable machining, or being used in combination with assembling of other thermal conductive bars (Step S104). A first embodiment of the light core structure according to the present invention comprises a cylindrical thermal conductive body 1 and an end and a circumferential surface of the thermal conductive body 1 are respectively provided with a plurality of LEDs 10 mounted thereto. Each LED 10 is electrically connected through the conductive metal wiring 11.

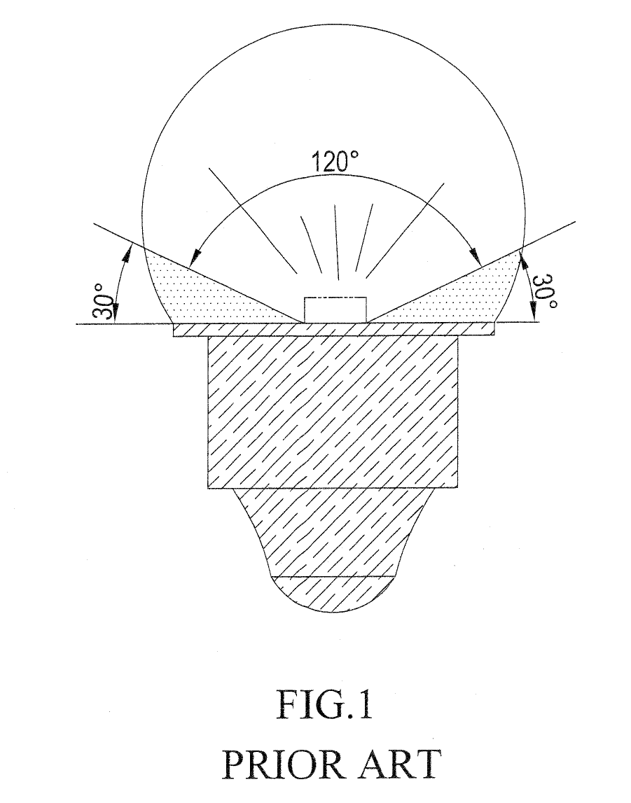

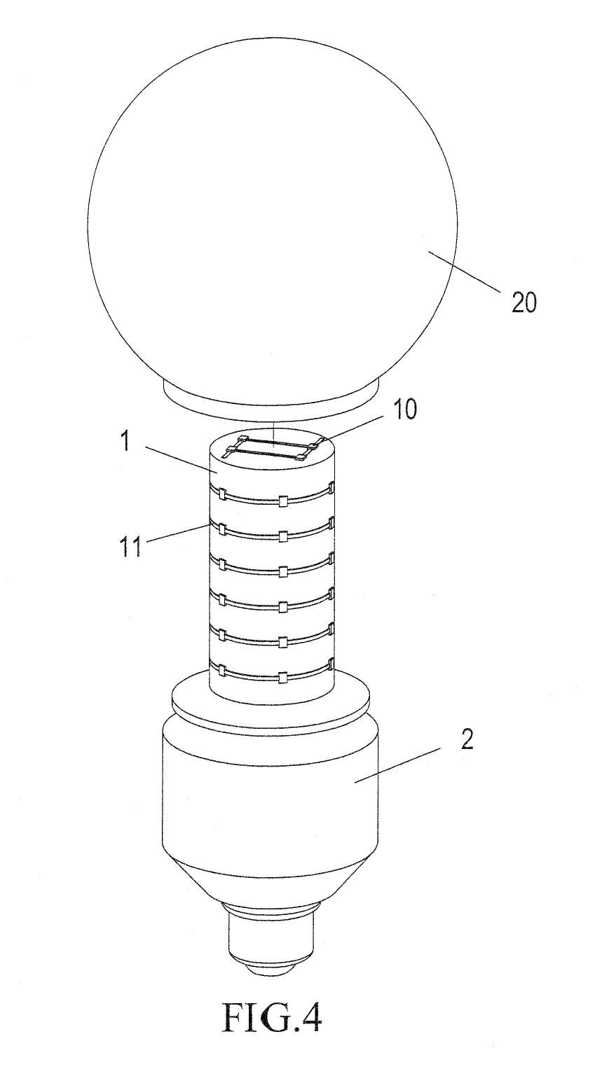

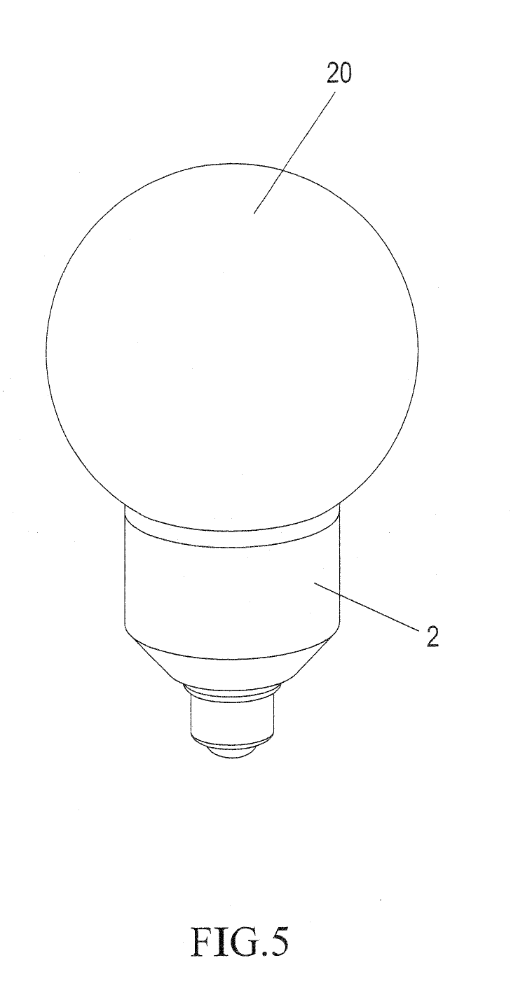

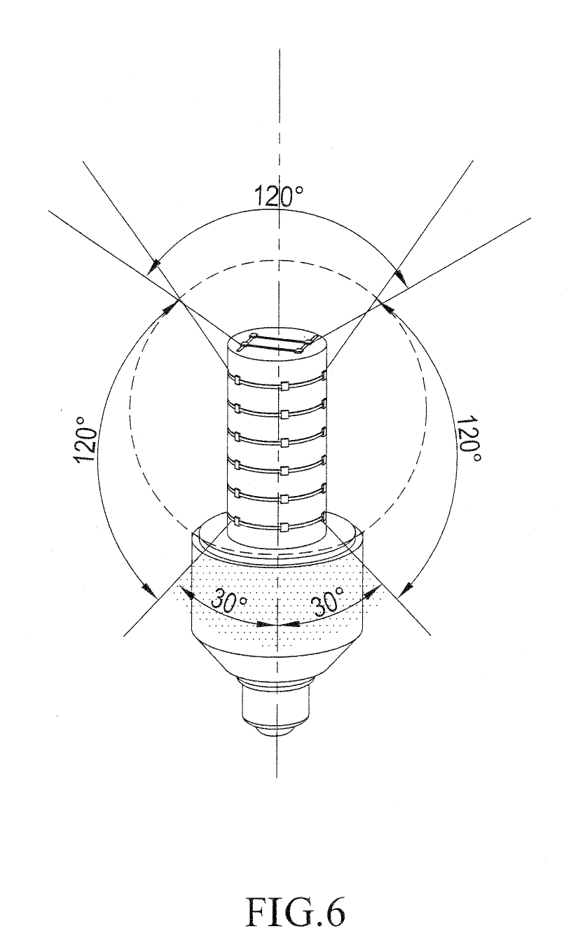

Referring to FIGS. 4, 5, and 6, the top end and the cylindrical-shaped circumferential surface of the thermal conductive body 1 are mounted with multiple rows of LEDs 10 and can be used to replace the conventional flat board LED light-emitting module through threading or other suitable machining or being used for assembling in combination with other thermal conductive bar. The thermal conductive body 1 is formed on a surface of an adaptor element 4. The adaptor element 4 is provided on a light stem 2. A cover 20 is coupled to the light stem 2 to fix the thermal conductive body 1 inside the cover 20. As shown in FIGS. 1 and 2, according to the present invention, the LEDs 10 are mounted to an end face and a circumferential surface of the thermal conductive body 1. With such an arrangement, when the LEDs 10 emit light, the lights emitting from these LEDs 10 may overlap and supplement each other so as to make an illumination range that is close to 360 degrees. The heat generated at the time when the LEDs 10 emits light is conducted off by the thermal conductive body 1 to dissipate to the atmosphere so that overheating and thus damage of the LEDs 10 are eliminated.

According to the technique of illuminating from the circumferential surface in combination with the top end face of the thermal conductive body 1 of the present invention, the portion that is conventionally subtracted from the hemispherical range in the longitudinal axis can be supplemented and in addition, extension is also possible to a range of 60 degrees of a lower hemisphere under the lateral axis, with only 30 degrees that are the partially dark zone left. This partially dark zone is exactly corresponding to the bulb head so that the completely dark zone that conventionally exists is eliminated and the drawback of the conventional LED light discussed above can thus be overcome.

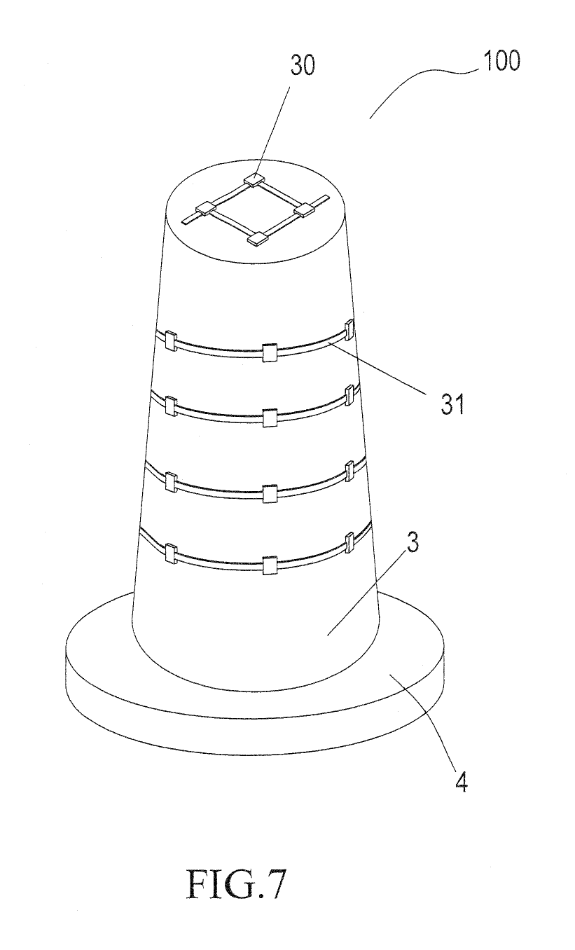

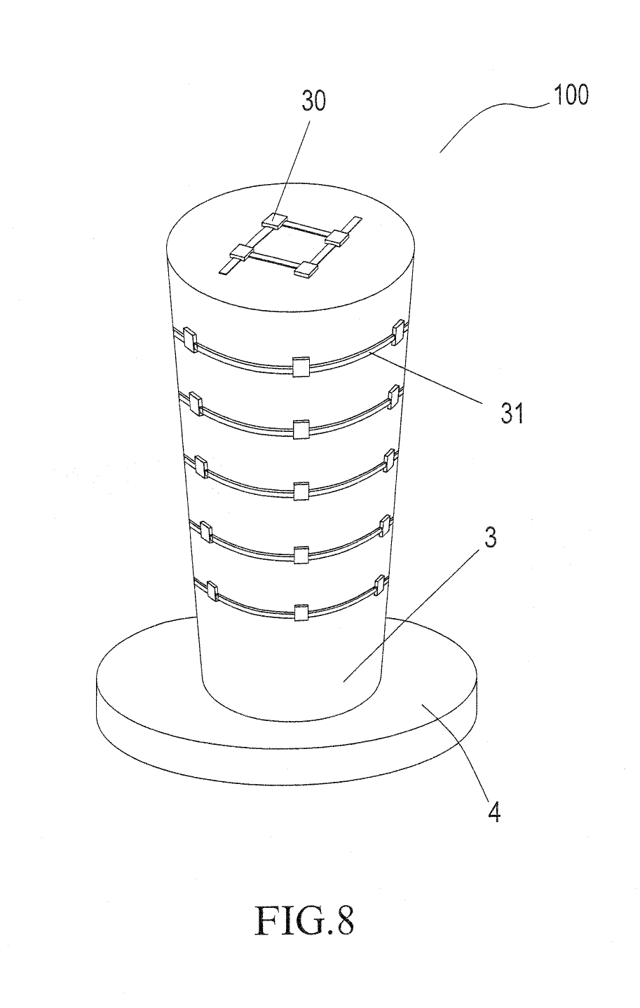

Referring to FIGS. 7 and 8, a second embodiment of the present invention, as shown in FIG. 7, comprises a conical pillar like thermal conductive body 3, which is a first configuration of the instant embodiment.

The thermal conductive body 3 has a small area end face and a circumferential surface to which a plurality of LEDs 30 are respectively mounted. Each LED 30 is electrically connected through conductive metal wiring 31. As shown in FIG. 8, a second configuration of the instant embodiment is illustrated, in which the LEDs 30 that are mounted to the small area end face are moved to the large area end face.

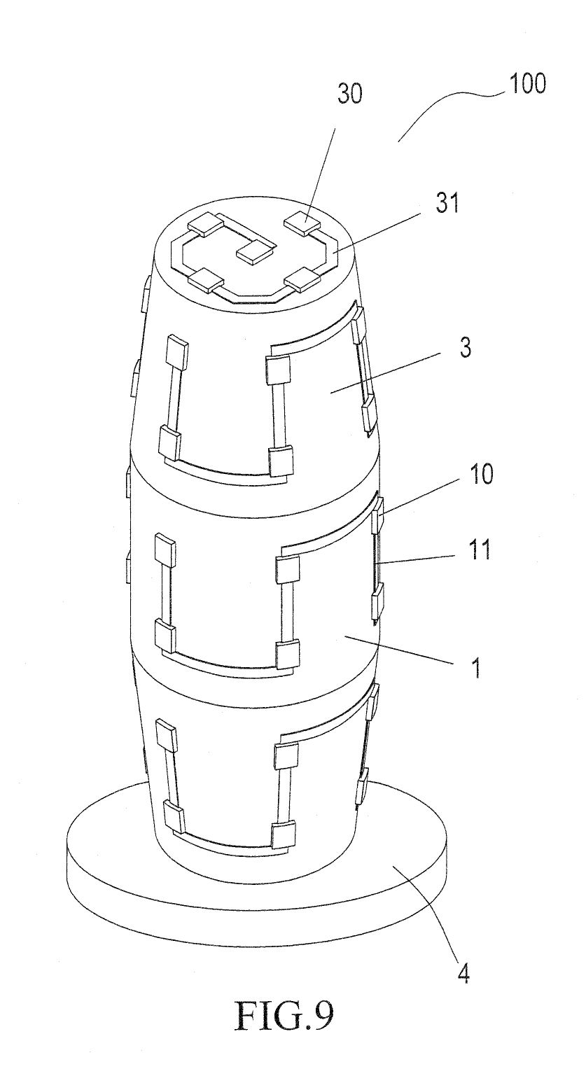

Referring to FIG. 9, a cylindrical thermal conductive body 1 according to the first embodiment of the present invention has two opposite ends to which conical pillar like thermal conductive bodies 3 according to the second embodiment of the present invention are respectively mounted to form a light core structure in the form of a pillar like object. With this arrangement, the illumination brightness and the illumination range can both be increased. The pillar like object has two end faces and a circumferential surface to which a plurality of LEDs 10, 30 is respectively mounted with each of the LEDs 10, 30 being electrically connected through conductive metal wiring 11, 31.

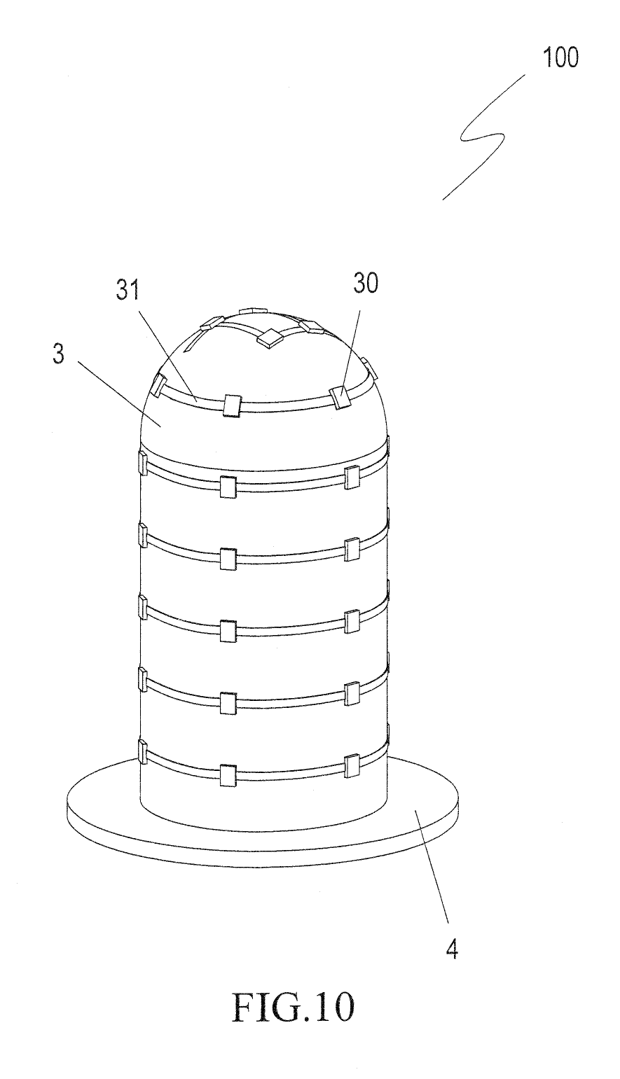

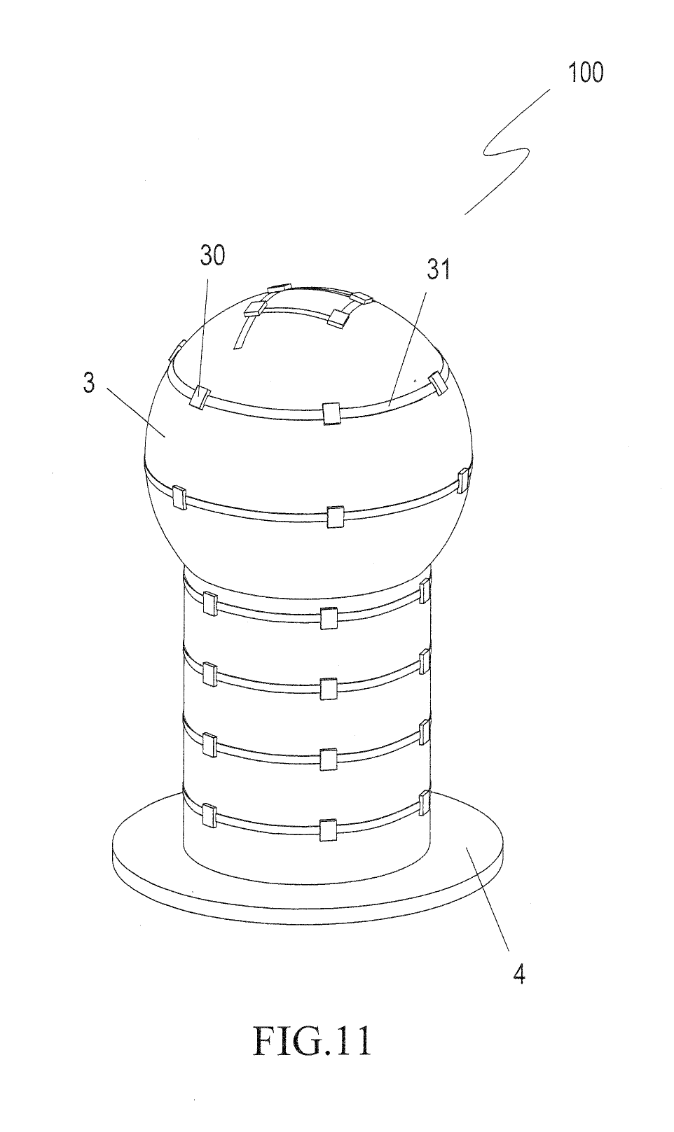

Referring to FIGS. 10 and 11, a third embodiment of the present invention, as shown in FIG. 10, comprises a spherical-ended pillar like thermal conductive body 3 that is a first configuration of the instant embodiment. A spherical end face and a circumferential surface of the thermal conductive body 3 is provided with a plurality of LEDs 30 mounted thereto. Each LED 30 is electrically connected through conductive metal wiring 31. As shown in FIG. 11, a second configuration of the instant embodiment is illustrated, in which the LEDs 30 that are mounted to the spherical face that is relatively small are moved to an expanded spherical face that is relatively large.

Further, according to the present invention, the thermal conductive body 1 can be one of a cylindrical shape, a circular tubular shape, a spherical pillar shape, and a conical pillar shape and is made of one of thermally conductive ceramic materials, plastics, resins, insulation-coated metals, and glass. The adaptor element 4 is made of one of metal and alloys thereof, plastics that are temperature resistant and thermally conductive, and thermally conductive ceramics and has a surface to which a plurality of LEDs 10 is mounted with each LED 10 being electrically connected. Alternatively, there can be no LED mounted on the adaptor element.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A manufacturing process of light core structure, comprising the following steps:
(1) using an insulation material that is temperature resistant and has high thermal conductivity to serve as a base material, using the base material to form a thermal conductive body;
(2) after Step (1), applying techniques selected from curved surface printing, transferring, and transfer printing to print solderable conductive metal wiring on a surface of the thermal conductive body and applying heat to cure the wiring to form a curved surface circuit;
(3) after Step (2), applying bonding technique and soldering oven facility, together with a fixture, to mount at least one light-emitting element to the curved surface of the thermal conductive body through soldering; and
(4) after Step (3), coupling the thermal conductive body to an adaptor element.

2. The manufacturing process of light core structure according to claim 1, wherein the thermal conductive body is one of a cylindrical shape, a circular tubular shape, a spherical pillar shape, and a conical pillar shape.

3. The manufacturing process of light core structure according to claim 1, wherein the thermal conductive body 1 trol unit further has a switch exposed on an external surface of said body member for manually turning on and off said automatic audio playing device.

4. The manufacturing process of light core structure according to claim 1, wherein the adaptor element is made of one of metal and alloys thereof, plastics that are temperature resistant and thermally conductive, and thermally conductive ceramics.

5. The manufacturing process of light core structure e according to claim 1, wherein the adaptor element has a surface to which a plurality of LEDs is mounted, each of the LEDs being electrically connected.

6. The manufacturing process of light core structure according to claim 1, wherein the light-emitting element comprises an LED or an SMD LED.

7. A light core structure, comprising:
a thermal conductive body, which has an end face and a circumferential surface to each of which at least one light-emitting element is mounted, the light-emitting element being electrically connected.

8. The light core structure according to claim 7, wherein the thermal conductive body is one of a cylindrical shape, a circular tubular shape, a spherical pillar shape, and a conical pillar shape.

9. The light core structure according to claim 7, wherein the light-emitting element comprises an LED or an SMD LED.

10. A light core structure, comprising:
at least one cylindrical thermal conductive body, which has a circumferential surface to which at least one light-emitting element is mounted, the light-emitting element being electrically connected; and
two conic pillar like thermal conductive bodies, which are respectively mounted to two ends of the cylindrical thermal conductive body, each of the conic pillar like thermal conductive bodies comprising an end face and a circumferential surface to each of which at least one light-emitting element is mounted, the light-emitting element being electrically connected.
